(19) United States
(12) Patent Application Publication
(10) Pub. No.: US 2007/0182596 A1
(43) Pub. Date: Aug. 9, 2007

(54) Key Construction Method For A Keyboard and The Keyboard Thereof

(76) Inventor: Jason Chen, Sijhih City (TW)

Correspondence Address: BAYSHORE PATENT GROUP, LLC, 520 CHANTECLER DR., FREMONT, CA, 94539, US

(21) Appl. No.: 11/467,563

(22) Filed: Aug. 28, 2006

Related U.S. Application Data
(63) Continuation-in-part of application No. 10/703,782, filed on Nov. 8, 2003, now abandoned.

(51) Int. Cl. H03M 11/00

(52) U.S. Cl. 341/26

(57) ABSTRACT

A key constructing method for a keyboard has M scan lines * N return lines. The electrical interconnects of the M scan lines*N return lines can generate numerical electrical contacts of A₁ to A_{M*N}, while the numerical electrical contacts of {A₁ to A_{M*N}}are the electrical contact set {A}. This key constructing method for the keyboard comprises the steps of: selecting at least one or more electrical contacts from the electrical contact set {A} to create an electrical contact set {B}; creating the electrical contact set {C}, while the electrical contact set {C}=the electrical contact set {A}−the electrical contact set {B}; combining at least one electrical contact from the electrical contact set {C} with one of the electrical contacts from the electrical contact set {B} to generate an expanded key; and, or, after the expanded key is pressed, outputting at least one or more key codes by the keyboard, wherein the key codes are used to recognize the expanded key.

This application is a Continuation-in-Part of application Ser. No. 10/703,782, filed on Nov. 8, 2003.

### FIELD OF THE INVENTION

The present invention relates to a key constructing method for a keyboard, and more particularly to a method of expanding the number of keys on a keyboard without increasing the number of scan/return lines. The expanded keys generated for a keyboard can be used as hot keys.

### BACKGROUND OF THE INVENTION

Taiwanese Patent Application Publication No. 402123 (i.e., “The keyboard device with expandable function keys”) describes that “A keyboard device with expandable function keys, comprises a keyboard and multiple expandable function keys on the keyboard”. In this prior art, the function keys are required to be connected to the additional Input/Output signal lines of the microprocessor circuit inside the keyboard. These additional Input/Output signal lines are to be combined with the original key matrix of the keyboard to create a new key matrix, which will encode the function keys in such a way that the key codes can be recognized by the Windows application software. An user can use a keyboard to directly control the features of peripheral devices and to know the controlling result from a displaying screen. However, there are several drawbacks in this prior art. It needs additional Input/Output lines connected to the microprocessor circuit in order to expand the number of function keys. Moreover, the prior art significantly increases the manufacturing cost of the keyboard.

In order to overcome the disadvantage of the prior art, the present invention provides an improved key constructing method of the keyboard. Other relevant prior arts could be found in U.S. Pat. No. 6,680,676 (Hayashi et al.) and U.S. Pat. No. 6,417,787 (Hsu J.). However, the present invention invents a new key constructing method for a keyboard not disclosed in the above two publications.

### SUMMARY OF THE INVENTION

The present invention describes a key constructing method for a keyboard. This key constructing method can be applied to expand the number of the keys on a keyboard while without increase the number of scan/return lines. Moreover, the expanded keys generated for the keyboard can be used as hot keys.

In order to achieve the goal of the invention, the present invention describes a key constructing method for a keyboard. This key constructing method can be used for a keyboard having M scan lines * N return lines. The M scan lines * N return lines can generate the electrical contacts of A₁, A₂, A₃, . . . to A_{M*N}, while the electrical contacts of {A₁, A₂, A₃, . . . , A_{M*N}} are the electrical contact set {A}. This key constructing method comprises the following steps: selecting at least one or more electrical contacts from the electrical contact set {A} in order to create an electrical contact set {B}; creating an electrical contact set {C}, while the electrical contact set {C}=the electrical contact set {A}−the electrical contact set {B}; and combining at least one electrical contact from the electrical contact set {C} with one of the electrical contacts from the electrical contact set {B} to generate an expanded key.

Another embodiment of the present invention describes a key constructing method for a keyboard. A key constructing method for a keyboard of the present invention has M scan lines * N return lines. The M scan lines and N return lines can generate the scan/return lines of A₁, A₂, A₁,A₃, . . . , A_{M+N}. The scan/return lines of {A₁, A₂, A₁,A₃, . . . , A_{M+N}} are the scan/return set {A}. This key constructing method for the keyboard comprising the steps of: selecting at least one or more scan/return lines from said scan/return line set {A} to create a scan/return line set {B}; creating a scan/return line set {C}, wherein the scan/return line set {C}=the scan/return line set {A}−the scan/return line set {B}; creating a key matrix circuit by the scan/return line set {C}; and generating an expanded key by using the key matrix circuit and one of the scan/return lines set {B}.

### BRIEF DESCRIPTION OF THE DRAWINGS

FIG. 1 is a keyboard functional block diagram illustrating the first and the second method of the present invention;

FIG. 2 is a flow chart showing the first method of the present invention; and

FIG. 3 is a flow chart showing the second method of the present invention.

### DETAILED DESCRIPTION OF THE INVENTION

The present invention can expand the number of keys on a keyboard without increasing the number of scan/return lines. In general, the key generated by using the method described in the present invention is called the expanded key. Such expanded key can be applied as a hot key in an application.

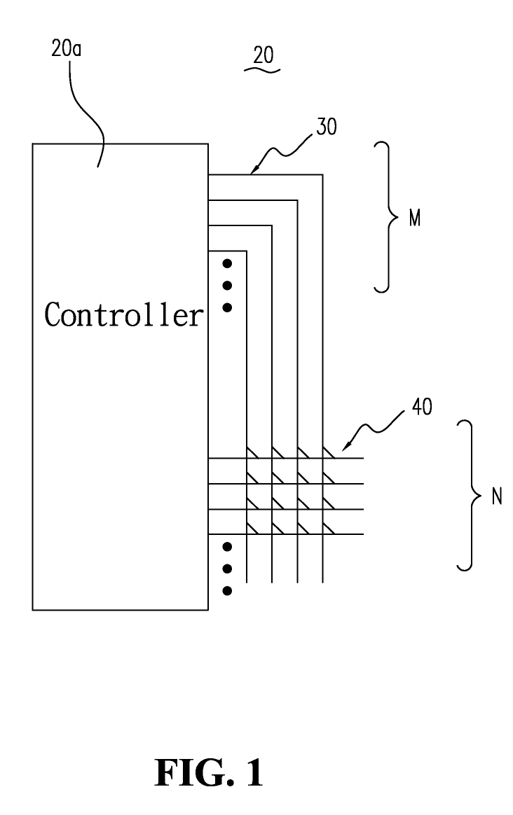

Referring to FIG. 1, a keyboard functional block diagram is shown to illustrate the first and the second methods of the present invention. The hardware circuitry of the keyboard 20, the controller 20a, comprises M scan lines 30 and N return lines 40. Anyone who is ordinarily skilled in the art understands that M scan lines 30 and N return lines 40 generate M*N electrical contacts of A₁, A₂, A₃, . . . to A_{M*N}, while each electrical contact represents a switch on the hardware circuitry of the keyboard. In the present invention, the “M*N electrical contacts of A₁, A₂, A₃, . . . to A_{M*N}” are called the electrical contact set {A}. The feature of the first method of the present invention is how to arrange the electrical contact set {A} in order to generate an expanded key. Similarly, as shown in FIG. 1, controller 20a comprises M scan lines 30 and N return lines 40. Ordinary persons skilled in the art understands that M scan lines 30 and N return lines 40 can generate M+N scan/return lines of A₁, A₂, A₃, . . . to A_{M+N}. Each scan/return line and the other scan/return line intersect with each other, and each intersection point represents a switch on the hardware circuitry of the keyboard.

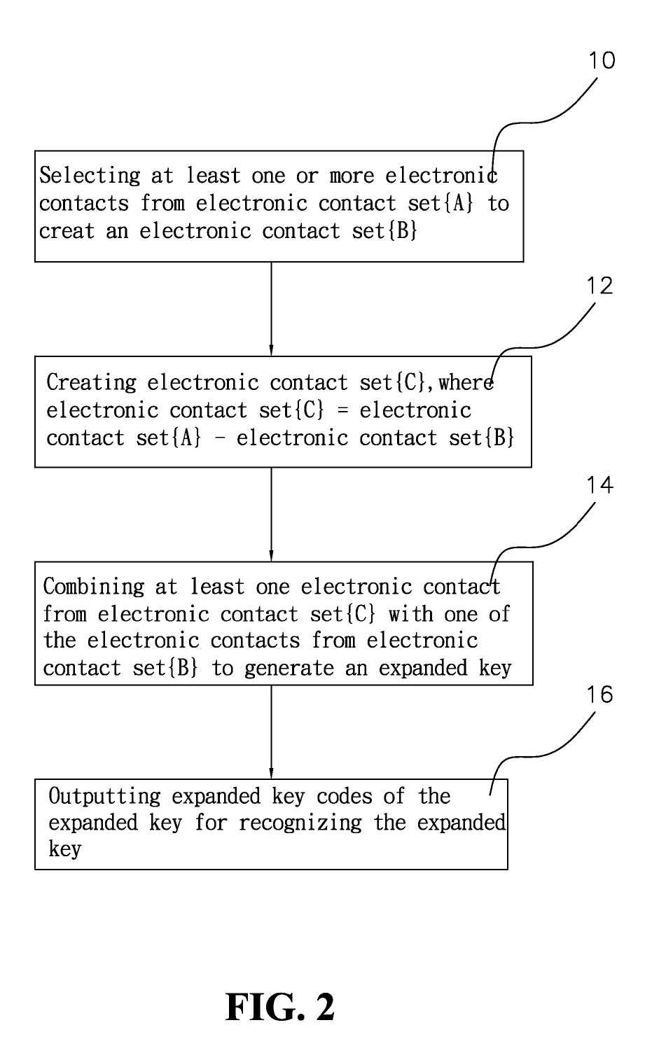

Referring now to FIG.2, a flow chart is shown to outline the first method of the present invention. In step 10, at least one or more electrical contacts are selected from the electrical contact set {A} to create an electrical contact set {B}. Taking a keyboard with 16 scan lines 30*8 return lines 40 for example, that is, in this embodiment, M=16, N=8, 16 scan lines 30*8 return lines 40 can generate 128 electrical contacts of A₁, A₂, A₃, . . . , A₁₂₈, while the electrical contact set {A} is {A₁, A₂, A₃, . . . to A₁₂₈}. An electrical contact A₁, for example, is chosen as the electrical contact set {B}, that is, the electrical contact set {B} is {A₁}. Of course, according to step 10, two or more electrical contacts can be chosen as the electrical contact set {B}, however, in order to make the present invention easier to understand, only one electrical contact is chosen as the electrical contact set {B} in this embodiment.

In step 12, an electrical contact set {C} is created. The electrical contact set {C}=the electrical contact set {A}−the electrical contact set {B}, that is, the remainder of the electrical contact set {A} minus the electrical contact set {B} forms the electrical contact set {C}. By using the same embodiment as in the previous step, after subtracting {A₁} from {A₁, A₂, A₃, . . . , A₁₂₈}, the remainder is {A₂, A₃, . . . , A ₁₂₈}, that is, the electrical contact set of {C} is equal to {A₂, A₃, . . . , A₁₂₈}.

In step 14, at least one electrical contact from the electrical contact set {C} is combined with at least one of the electrical contacts from the electrical contact set {B} to generate an expanded key. By using the same embodiment as above, the electrical contact set {C} is {A₂, A₃, . . . , A₁₂₈}, while the electrical contact set {B} is {A₁}. The examples for the generation of the expanded keys are listed in the following: for example, the electrical contacts of {A₁, A₂} can generate an expanded key. Same analogy applies to the electrical contacts of {A₁, A₃}, {A₁, A₄}, {A₁, A₅}, {A₁, A₆}, . . . to the electrical contacts of {A₁, A₁₂₈} can generate an expanded key. Therefore, such method can generate total 127 expanded keys.

From step 10 to step 14, one can understand that the number of keys on keyboard 20 can be very easily expanded without increasing the number of scan lines 30 and return lines 40. As for the number of expanded keys based on the same embodiment, when the electrical contact set {B} is {A₁}, 127 expanded keys can be generated. By adding the generated 127 expanded keys with the 127 original keys generated from the electrical contacts of {A₂, A₃, . . . , A₁₂₈}, there are at least 254 keys can be generated by 8*16 scan lines 30 and return lines 40. As a result, while comparing to the conventional method of the keyboard which normally generate only 128 keys, the present invention can generate much more keys on the keyboard.

Detailed examples for the embodiments of the electrical contact set {B} being {A₁, A₂} are described in the following order. The examples of the electrical contact set {B} can include, but not limited to, one electrical contact of {A₁}; two electrical contacts of {A₁, A₂}, or three or more electrical contacts. For example, for the purpose of generating expanded keys, the electrical contact set {B} is {A₁, A₂}, and the electrical contact set {C} is the expanded keys of {A₃, . . . , A₁₂₈}. Examples of the expanded key of the electrical contacts of {A₁, A₃}, the expanded key of the electrical contacts of {A₁, A₄}, the expanded key of the electrical contacts can include, but not limit to, {A₁, A₅}; {A₁, A₆}; {A₁, A₇}, etc, to {A₁, A₁₂₈}.

In addition, the detailed examples for the embodiments of the expanded keys of the electrical contact set {C} can include, but not limit to, {A₂, A₃}; {A₂, A₄}; {A₂, A₅}; {A₂, A₆}; {A₂, A₇}, . . . etc, to {A₂, A₁₂₈}. Therefore, there are total 252 (126*2) expanded keys can be generated by the above embodiments and analogy. These 252 expanded keys plus 126 original keys generated from the electrical contacts of {A₃, . . . , A₁₂₈}, at least 378 keys can be generated from the 8*16 scan lines 30 and return lines 40, which is far beyond the 128 keys as one knows from the ordinary skill in the art.

In step 16, while the expanded keys generated by all the electrical contacts, after the expanded keys are pressed, the keyboard 20 outputs at least one or more key codes while some of them are used to recognize the expanded keys. Step 16 is described by using the same embodiment as above, for example, the expanded key can be generated by the electrical contacts of {A₁, A₂}. The electrical contacts of {A₁, A₂} can generate two electrical contacts of the expanded keys. The keyboard 20 then outputs at least one or more key codes while some of them can be used to recognize the expanded key. In other words, after pressing the expanded key generated by the electrical contacts of {A₁, A₂}, keyboard 20 then outputs at least one or more key codes. Therefore, the key code receiver, i.e. the computer, can use the outputting key codes to recognize this expanded key. In the present invention, the implementation of the first key code can be a special code when the keyboard outputs two or more key codes. The corresponding special code for the first key code of the expanded key generated by equating the electrical contact set {B} to the electrical contact of {A₁} is E0, while the corresponding special code for the first key code of the expanded key generated by equating the electrical contact set {B} to the electrical contact of {A₂} is E1. Therefore, in the present invention, when the keyboard outputs one or more key codes, the first key code can be either a special code or a normal key code. Accordingly, the second code is a normal key code.

Based on the present invention, keyboard 20 comprises: M scan lines 30 and N return lines 40, while M scan lines 30 and N return lines 40 generate electrical contacts of A₁, A₂, A₃, . . . to A_{M*N}. The expanded keys comprises two or more electrical contacts of A₁, A₂, A₃, . . . to A_{M*N}. In the present invention, keyboard 20 further comprises at least one or more key codes which are used to recognize the expanded keys. In addition, the first key code of the one or more key codes of keyboard 20 is a special code.

Furthermore, based on the present invention, keyboard 20 comprises: M scan lines 30 and N return lines 40, while M scan lines 30 and N return lines 40 generate electrical contacts of A₁, A₂, A₃, . . . to A_{M*N}. The expanded keys comprises two or more electrical contacts of A₁, A₂, A₃, . . . to A_{M*N}. When the expanded keys are pressed, the keyboard 20 does not output any key codes.

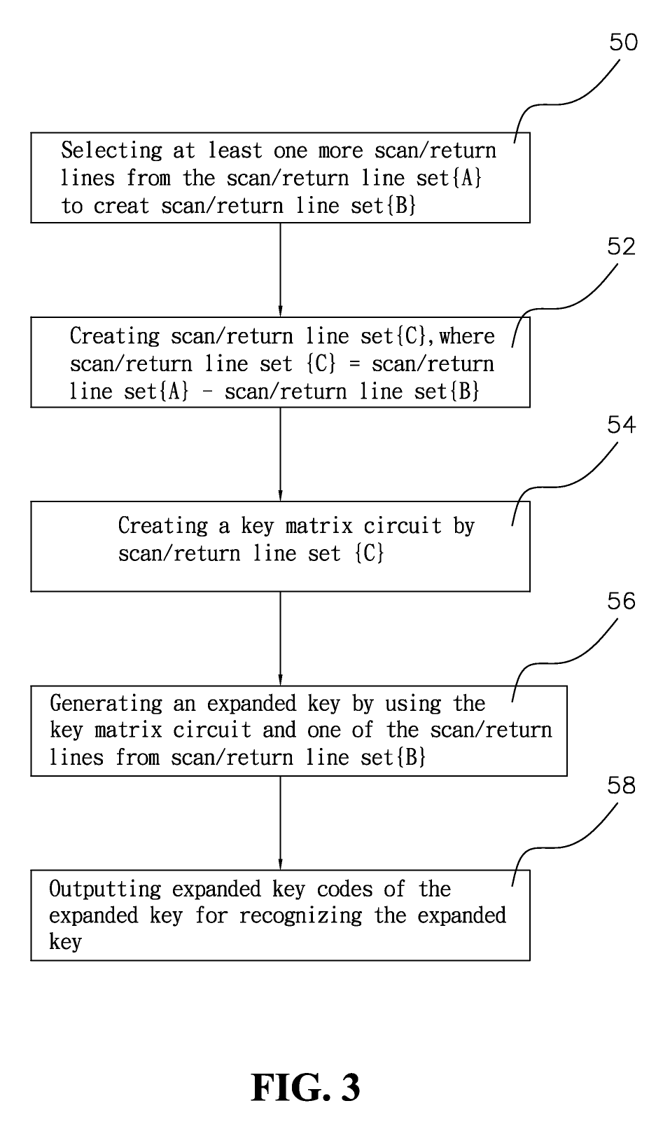

Referring now to FIG.3, a flow chart of the second method of the present invention is shown. Similarly, the second method of the present invention can be used for a keyboard 20 with M scan lines 30 and N return lines 40, while M scan lines 30 and N return lines 40 can generate the scan/return lines of A₁, A₂, A₃, . . . to A_{M+N}. In the present invention, the scan/return lines of {A₁, A₂, A₃, . . . A_{M+N}} is the scan/return line set {A}.

In step 50, at least one or more scan/return lines are selected from the scan/return line set {A} in order to generate a scan/return line set {B}. For example, by taking a keyboard with 8 scan lines 30*16 return lines 40, that is, M=8, N=16 in this embodiment, then the 8 scan lines 30*16 return lines 40 can generate 24 scan/return lines of A₁, A₂, A₃, . . . to A₂₄, while the scan/return line set {A} is { A₁, A₂, A₃, . . . , A₂₄}. In this embodiment, one scan/return line A₁ is selected to be the scan/return line set {B}, that is, the electrical contact set {B } is equal to {A₁}. According to the present invention, two or more scan/return lines can be used for the scan/return line set {B}. However, in order to simplify the embodiment and to make the present invention easier to be understood, only one scan/return line is selected to be the scan/return line set {B}.

In step 52, the scan/return line set {C} is created. The scan/return line set {C}=the scan/return line set of {A}−the scan/return line set {B}. By using the same analogy described above, the scan/return line set {C} equals to {A₂, A₃, . . . , A₂₄} can be calculated by subtracting {A₁}from the remainder of {A₁, A₂, A₃, . . . , A₂₄} to obtain a result of {A₂, A₃, . . . , A₂₄}.

In step 54, a key matrix circuit is created from the scan/return line set {C}.

In step 56, an expanded key is generated by combining the key matrix circuit with one of the scan/return lines from the scan/return line set {B}.

In step 54 and 56, the scan/return line set {C} is {A₂, A₃, . . . , A₂₄}, while the scan/return line set {B} is {A₁}. According to step 54, a key matrix circuit is created from the scan lines 30 and the return lines 40 of the scan/return line set {C}, and all the keys of this key matrix circuit are normal keys with single electrical contact. According to step 56, part or all of the key matrix circuit will be duplicated. A key of two electrical contacts are generated by combining one of the scan lines 30 or return lines 40 from the originally created key matrix circuit with one of the scan/return lines from the scan/return line set {B} in the direction of row or column. This newly generated key with two electrical contacts is the expanded key of the present invention.

In step 58, based on the expanded keys generated by all the electrical contacts, after the expanded keys are pressed, the keyboard 20 outputs at least one or more keyboard codes, some of which are used for recognizing the expanded keys. Since step 58 is similar with step 16, step 58 will not be repeated here.

Furthermore, based on the expanded keys generated by all the electrical contacts, after the expanded keys are pressed, the keyboard 20 does not output any key codes.

By applying the first and the second method of the present invention, the keyboard 20 can be used applied as a computer keyboard, or the key input device for portable electronic devices; such as notebook computers, personal data assistance devices, mobile phone, and other applicable electronic devices.

Those ordinarily skilled in the art should understand that many modifications and variations are possible in light of the above teaching for the present invention. The scope of the invention is intended to be defined by the claims appended hereto and their equivalents.

What is claimed is:

1. A key constructing method for a keyboard having M scan lines and N return lines, wherein M scan lines*N return lines generate electrical contacts of A₁, A₂, A₃, . . . to A_{M*N}, and said electrical contacts of {A₁, A₂, A₃, . . . , A_{M*N}} is an electrical contact set {A}, comprising the steps of:
selecting at least one or more electrical contacts from said electrical contact set {A} in order to create an electrical contact set {B};
creating an electrical contact set {C}, wherein said electrical contact set {C}=said electrical contact set {A}−said electrical contact set {B}; and
combining at least one electrical contact from said electrical contact set {C} with one of the electrical contacts from said electrical contact set {B} to generate an expanded key.

2. The key constructing method of claim 1, comprising the further step of: based on all of the electrical contacts of said expanded key, after said expanded key is pressed, optionally outputting at least one or more key codes by said keyboard, wherein said key codes are used to recognize said expanded key.

3. The key constructing method of claim 2, wherein said expanded key is pressed, outputting said two or more key codes, the first key code of said key codes is a special code.

4. The key constructing method of claim 2, wherein said expanded key is pressed, outputting said one or more key codes, said codes are normal key codes.

5. The key constructing method of claim 1, wherein said expanded key is pressed, outputting none of said key codes.

6. A keyboard made by said method of claim 1.

7. A keyboard made by said method of claim 2.

8. A keyboard made by said method of claim 3.

9. A keyboard made by said method of claim 4.

10. A keyboard made by said method of claim 5.

11. A key constructing method for a keyboard having M scan lines and N return lines, wherein M scan lines and N return lines can generate scan/return lines of A₁, A₂, A₃, . . . to A_{M+N}, and said scan/return lines of {A₁, A₂, A₃, . . . , A_{M+N}} are a scan/return line set {A}, comprising the steps of:
selecting at least one or more scan/return lines from said scan/return line set {A} to create a scan/return line set {B};
creating a scan/return line set {C}, wherein said scan/return line set {C}=said scan/return line set {A}−said scan/return line set {B};
creating a key matrix circuit by said scan/return line set {C}; and
generating an expanded key by using said key matrix circuit and one of the scan/return lines from said scan/return line set {B}.

12. The key constructing method of claim 11, comprising further the step of: based on all of the electrical contacts of said expanded key, after said expanded key is pressed, optionally outputting at least one or more key codes by said keyboard, wherein said key codes are used to recognize said expanded key.

13. The key constructing method of claim 12, wherein said expanded key is pressed, outputting said two or more key codes, the first key code of said key codes is a special code.

14. The key constructing method of claim 12, wherein said expanded key is pressed, outputting said one or more key codes, said key codes are normal key codes.

15. The key constructing method of claim 11, wherein said expanded key is pressed, outputting none of said key codes.

16. A keyboard made by said method of claim 11.

17. A keyboard made by said method of claim 12.

18. A keyboard made by said method of claim 13.

19. A keyboard made by said method of claim 14.

20. A keyboard made by said method of claim 15.
